(19) United States
(12) Patent Application Publication
(10) Pub. No.: US 2026/0333605 A1
(43) Pub. Date: Oct. 22, 2026

(54) CAPTIVE DRIVER FOR WEDGELOCKS

(71) Applicant: BLUE ORIGIN MANUFACTURING, LLC, Huntsville, AL (US)

(72) Inventor: Robert Daniel Bertino, Puyallup, WA (US)

(21) Appl. No.: 19/184,924

(22) Filed: Apr. 21, 2025

(51) Int. Cl. H05K 7/14; B64G 1/22

(52) U.S. Cl. CPC H05K 7/1404; H05K 7/1412; B64G 1/2228

(57) ABSTRACT

Systems and methods disclosed herein are for a captive driver which may include a first interface on a first end of the captive driver and a second interface on a second end of the captive driver. The captive driver may be associated with a circuit board or card within an electronics box which is protected from an environment by a closeout cover or a lid. The second interface may extend or may be allowed to access the environment outside the electronics box. Operation of the second interface may allow operation of the captive driver and operation of the wedgelock to lock or unlock the circuit board or card with the electronics box remaining protected by the closeout cover or lid.

### TECHNICAL FIELD

The present disclosure is generally related to wedgelocks and methods associated therewith and, in at least one aspect, is specifically related to drivers for external access to wedgelocks.

### BACKGROUND

Launch vehicles include various components, including payload modules and control systems having circuit boards or cards installed and accessible within an electronics box. The inserted circuit boards or cards may be held within the electronics box by a wedgelock. A wedgelock may be a locking or clamping structural member having a locking feature which can expand circumferentially, radially, or outwards to lock against a receiving feature of the electronics box. A wedgelock may be used with a circuit board or card to lock or clamp the circuit board or card within the electronics box. The wedgelock may not be accessible once the electronics box has been assembled within other features of a payload module or control system. In one example, a closeout cover or lid for environmental protection may be provided over the electronics box. The use of the closeout cover or lid may contribute to additional loose hardware (such as fasteners, washers, and gaskets) or additional unique parts required to complete maintenance or installation of components of a launch vehicle.

### SUMMARY

In one non-limiting example, a captive driver may be an elongated structural member to allow external access, through a closeout cover or lid, for torquing wedgelocks associated with a circuit board or card. The torquing action may allow locking or unlocking for the circuit board or card against a receiving feature of an electronics box, without need to remove the closeout cover or lid. This may reduce hardware (such as fasteners, washers, gaskets) or additional unique parts required to complete maintenance or installation of components of a launch vehicle. In addition, the wedgelock may also provide conductive heat transfer to a chassis or other hardware of an electronics box. The captive driver may assist the wedgelock in the conductive heat transfer. A wedgelock may broadly encompass mechanical clamps having a locking feature which can expand circumferentially or outwards to provide a friction or other lock against the receiving feature of the electronics box.

In one non-limiting aspect, the captive driver or a system, including the captive driver, may permit access to hardware, such as a wedgelock, which may otherwise have limited access due, in part, to design constraints or to retrofit existing designs. The design constraints or existing designs of an electronics box may not normally be accessible once fully assembled, but a captive driver can extend a wedgelock used for locking and unlocking circuit boards or cards within the electronics board with a closeout cover or lid installed. The captive driver may extend access to the wedgelock to an area or an interface which is outside the electronics box. The captive driver may interface with the wedgelock on a first end and may be able to receive any suitable interface on a second end. The interface on the second end may be extended or allowed for access outside the electronics box. Further, operation of the interface may allow operation of the captive driver, which in turn allows operation of the wedgelock to lock or unlock a circuit board or card within the closeout cover or lid installed.

In another non-limiting aspect, the disclosure herein is for a method for locking or unlocking a circuit board or card in an electronics box. The method may include allowing a wedgelock to be associated with the circuit board or card and within the electronics box. The electronics box may be protected from an environment by a closeout cover or a lid. The method may include using a captive driver to access the wedgelock. The captive driver may have a first interface to the wedgelock on a first end of the captive driver and may have a second interface on a second end of the captive driver. The second interface may extend or be allowed for access outside the electronics box. The method may include operating the second interface to allow operation of the captive driver and operation of the wedgelock to lock or unlock the circuit board or card with the electronics box remaining protected by the closeout cover or lid.

### BRIEF DESCRIPTION OF THE DRAWINGS

Various features of the aspects described herein are set forth with particularity in the appended claims. The various aspects, however, both as to organization and methods of operation, together with advantages thereof, may be understood in accordance with the following description taken in conjunction with the accompanying drawings as follows:

FIG. 1 illustrates aspects of a system for locking or unlocking a circuit board or card in an electronics box, in accordance with at least one non-limiting aspect of the present disclosure;

FIG. 2A illustrates aspects of a captive driver in a cross-section of the electronics box, in accordance with a further non-limiting aspect of the present disclosure;

FIG. 2B illustrates further aspects of a captive driver in a cross-section of the electronics box, in accordance with a further non-limiting aspect of the present disclosure;

FIG. 3A illustrates aspects of an external interface and an additional interface of the captive driver prior to a compression movement to engage the captive driver, in accordance with a further non-limiting aspect of the present disclosure;

FIG. 3B illustrates aspects of the external interface and the additional interface of the captive driver after a compression movement to engage the captive driver, in accordance with a further non-limiting aspect of the present disclosure;

FIG. 3C illustrates different interchangeable external interfaces usable with a captive driver in a system for locking or unlocking a circuit board or card in an electronics box, in accordance with a further non-limiting aspect of the present disclosure;

FIG. 3D illustrate aspects of a captive driver, in accordance with a further non-limiting aspect of the present disclosure;

FIG. 4A illustrates aspects of an electronics box, in accordance with a further non-limiting aspect of the present disclosure;

FIG. 4B illustrates aspects of a captive driver and its engagement with the external interface and the additional interface using a seal, in accordance with a further non-limiting aspect of the present disclosure;

FIG. 4C illustrates aspects of a captive driver and an engagement interface of the external interface and the additional interface to the captive driver, in accordance with a further non-limiting aspect of the present disclosure;

FIG. 5 illustrates a method associated with a system for locking or unlocking a circuit board or card in an electronics box, in accordance with a further non-limiting aspect of the present disclosure; and

FIG. 6 illustrates a further method associated with a system for locking or unlocking a circuit board or card in an electronics box, in accordance with a further non-limiting aspect of the present disclosure.

### DETAILED DESCRIPTION

A captive driver may be inaccessibly located behind a closeout cover or lid, once an assembly of a component having the electronics box has been completed. An interface of the captive driver may extend or may be allowed to access an environment outside the electronics box. The interface may be on a first end of the captive driver and may be through an access feature of the closeout cover or lid. The interface may have an associated seal to protect the captive driver from the environment. Another interface on a second end of the captive driver may engage a wedgelock within the electronics box. Each wedgelock may be associated with a circuit board or card. Therefore, for one example, each circuit board or card may be associated with a captive driver, which may altogether be provided as a complete subassembly. The complete subassembly may be for an electronics box and may include all the hardware (such as multiple circuit boards or cards, the wedgelocks, and the captive drivers), individual/modular integrated closeout covers or lids having the access feature, and the seal for protection of the hardware within the electronics box from the environment.

The captive driver is able to address issues in a closeout cover or lid design which may cover the circuit board or card, but which may need to be removed for any access to the circuit board or lid. The captive driver may also address designed hardware which may be accessible from the outside, and which may remain exposed to the environments, which may reduce a life of the hardware. While individual gaskets, seals, and the like may be used for protection from the environment, the large exposed surfaces may still pose a challenge which may be addressed by the captive driver provided through an access feature of a closeout cover or lid and having a seal only as to the access feature.

In one example, the captive driver may be used in launch vehicles to provide access to wedgelocks as part of a space mission. In another example, the captive driver may be used in Earth-based applications, including in applications requiring deep access to a wedgelock that may be hidden or sealed behind a cover. Such applications may include movement applications having changing environments, such as airplanes, ground vehicles, spacecrafts, but may also include stationary applications where wedgelocks may be used. While a captive driver may be to engage wedgelocks, there may be additional examples of the captive driver used in a locking application which may require an extension of a tooling access to a lock interface which is behind a sealed cover, lid, or other covered system.

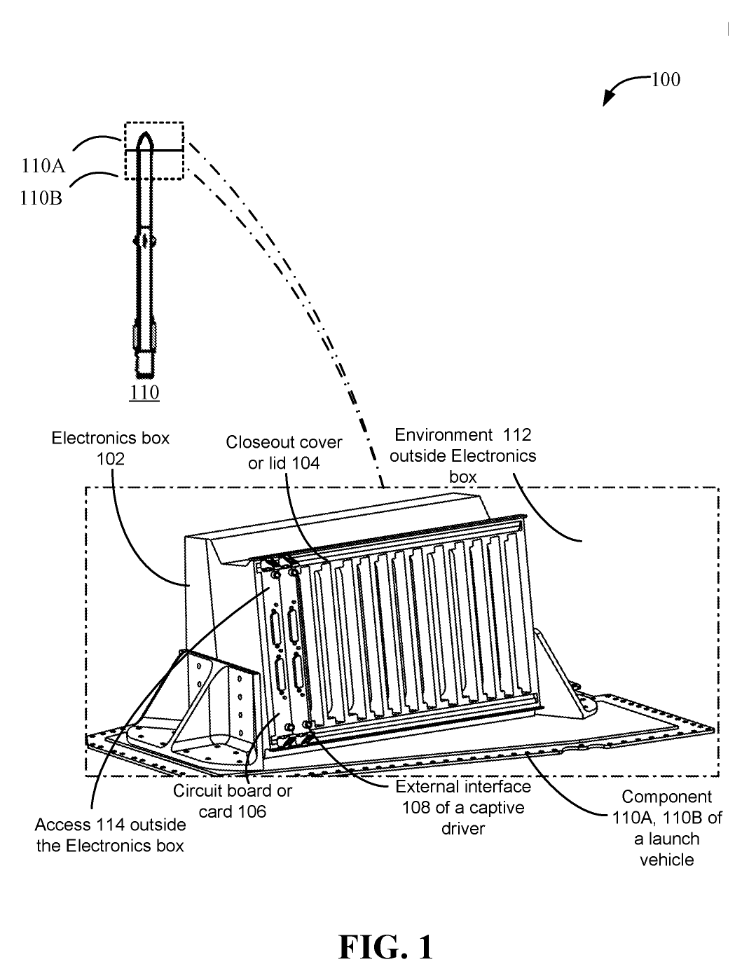

FIG. 1 illustrates aspects 100 of a system for locking or unlocking a circuit board or card in an electronics box, in accordance with at least one non-limiting aspect of the present disclosure. The aspects 100 may be a side view of the system. One or more components 110A, 110B of a launch vehicle 110 may include a circuit board or card in an electronics box. Although not marked, components under the illustrated components 110A, 110B including a first stage booster, may also benefit from the system for locking or unlocking a circuit board or card in an electronics box using a captive driver. For example, it may be possible to reduce hardware (such as fasteners, washers, gaskets) or additional unique parts required to complete maintenance or installation of components 110A, 110B of a launch vehicle 110. In addition, the wedgelock may also provide conductive heat transfer to a chassis or other hardware of an electronics box. The captive driver may assist the wedgelock in the conductive heat transfer.

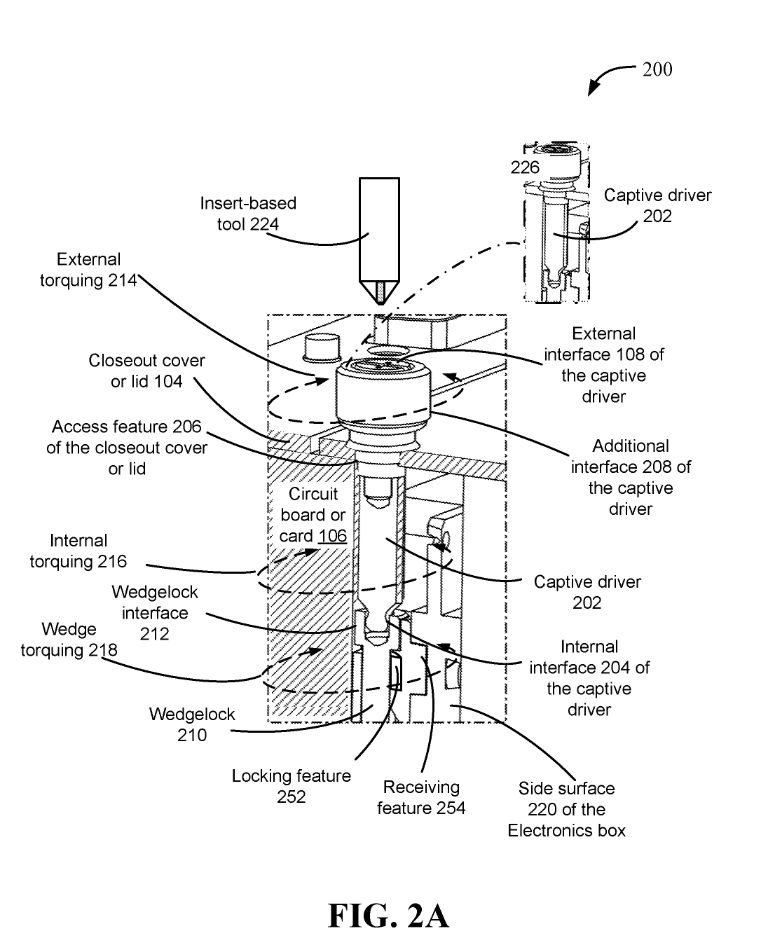

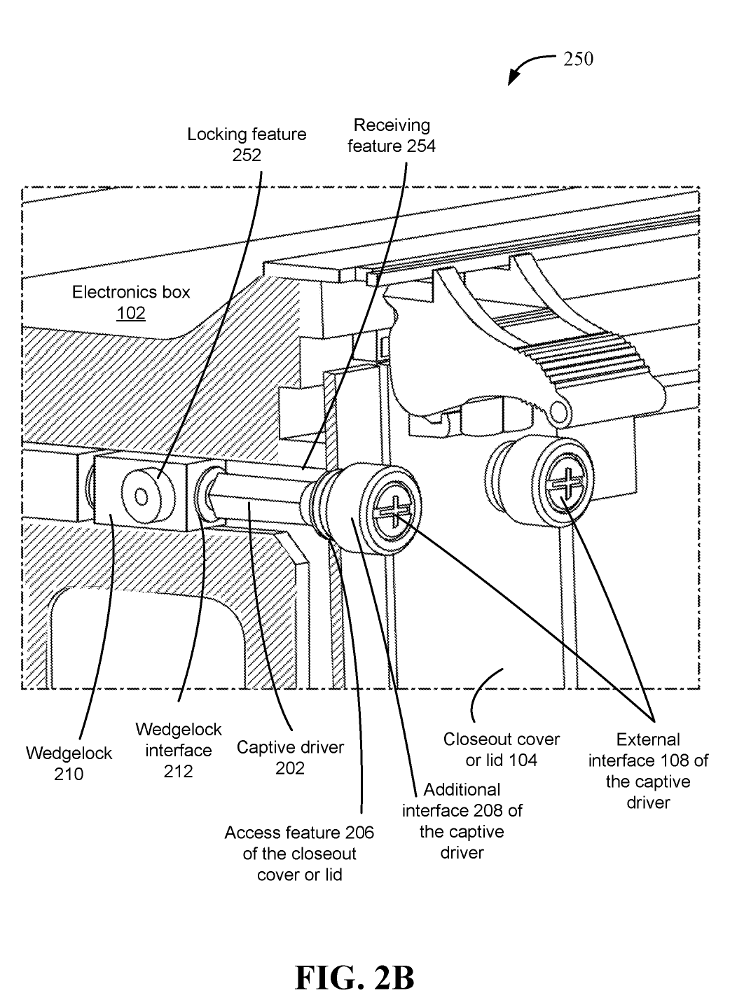

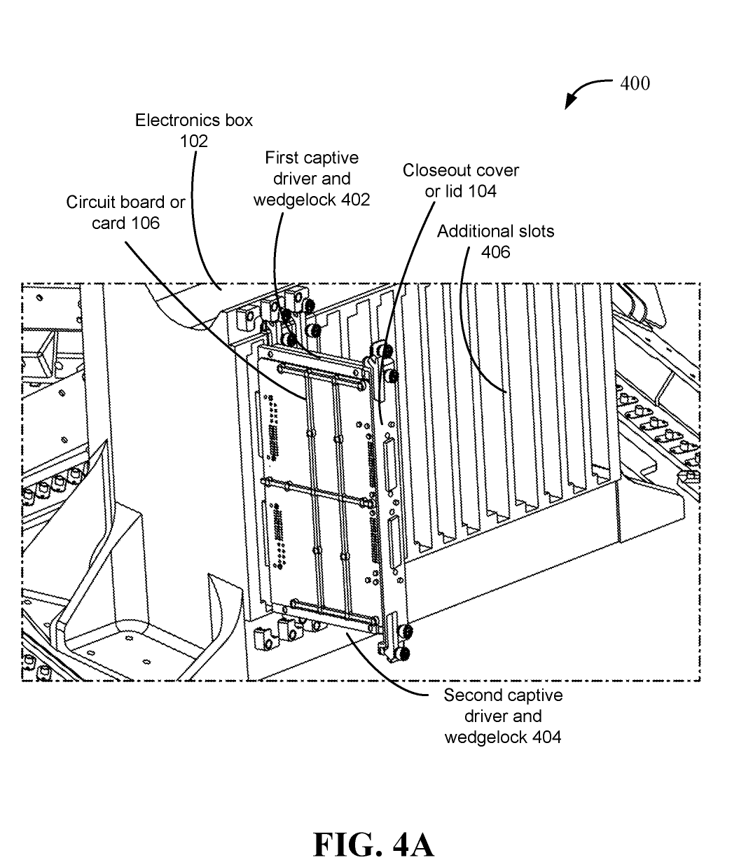

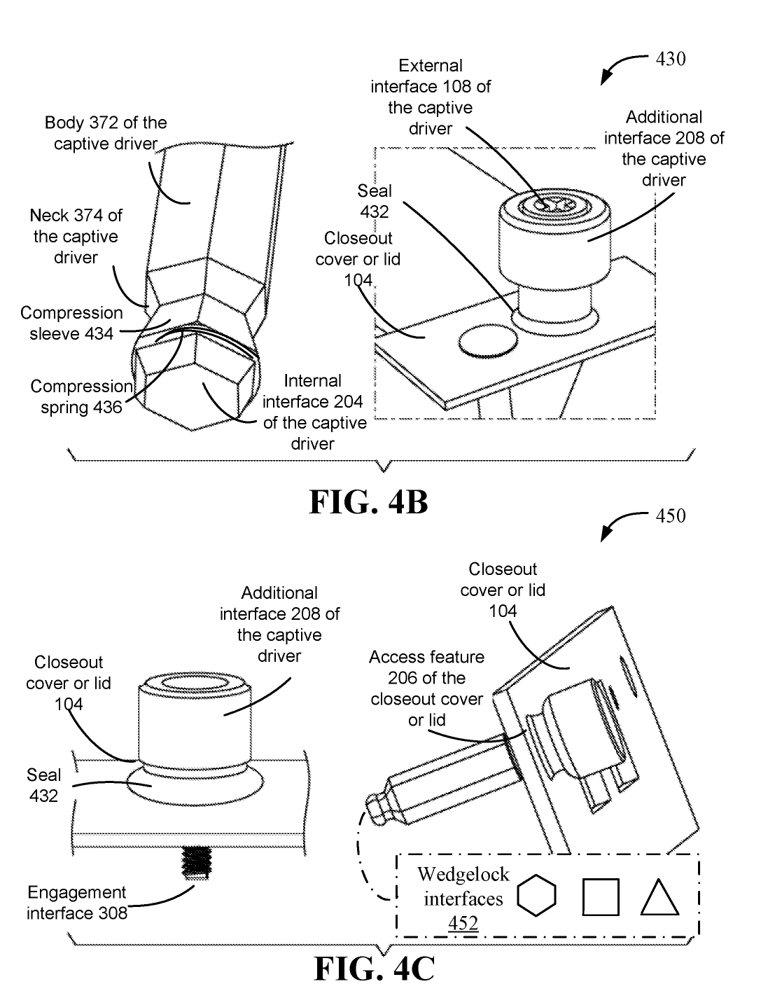

The system for locking or unlocking a circuit board or card 106 in an electronics box 102 may include the use of a wedgelock 210 (such as in FIG. 2). The wedgelock 210 may be associated with the circuit board or card 106 and may be located within the electronics box 102. The electronics box 102 may be protected from an environment 112 which is outside the electronics box (either in space or on Earth) by a closeout cover or a lid 104. The wedgelock 210 may not be accessible from outside the electronics box 102, at least in view of a closeout cover or a lid 104 sealing or being shut with respect to the electronics box 102. While only one circuit board or card 106 is marked, there may be multiple circuit boards or cards in additional slots 406 (as in FIG. 4A). The wedgelock 210 may be accessed 114 from outside the electronics box 102 by use of an external interface 108 of a captive driver 202 (such as in FIG. 2A).

FIG. 2A illustrates aspects 200 of a captive driver in a cross-section of the electronics box, in accordance with a further non-limiting aspect of the present disclosure. The captive driver 202 may include an internal interface 204 to the wedgelock 210 on a first end of the captive driver 202. The captive driver 202 may include the external interface 108 on a second end of the captive driver 202. The external interface 108, as illustrated in FIGS. 1 and 2A, may be extended or allowed for access 114 from outside the electronics box 102. The access 114 may be allowed through an access feature 206 of the closeout cover or a lid 104. The access 114 from outside the electronics box 102 ensures that operation of the external interface 108 allows operation of the captive driver 202. and operation of the wedgelock 210 to lock or unlock the circuit board or card 106 with the electronics box 102 remaining protected by the closeout cover or lid 104. For example, an operation of the external interface 108 may include turning the external interface 108 using a tool.

In one example, an additional interface 208, which is over the external interface 108 (but not enclosing the external interface 108 entirely), may allow grasp-based torquing of the captive driver 202 through the additional interface 208. This may be different from the external interface 108, which may only allow an insert-based torquing of the captive driver 202 using an insert-based tool 224. The grasp-based torquing or the insert-based torquing may be external torquing 214 operations passed to the captive driver 202. In one example, there may be an initial part of the torquing 214 operation that may not be passed to the captive driver 202 to allow an engagement of one or more of the external interface 108 or the additional interface 208 of the captive driver 202. Once engagement occurs, then all the torquing 214 may be passed to the captive driver. In another example, all of the torquing 214 may be passed to the captive driver without need for engagement if the captive driver is already engaged with one or more of the external interface 108 or the additional interface 208.

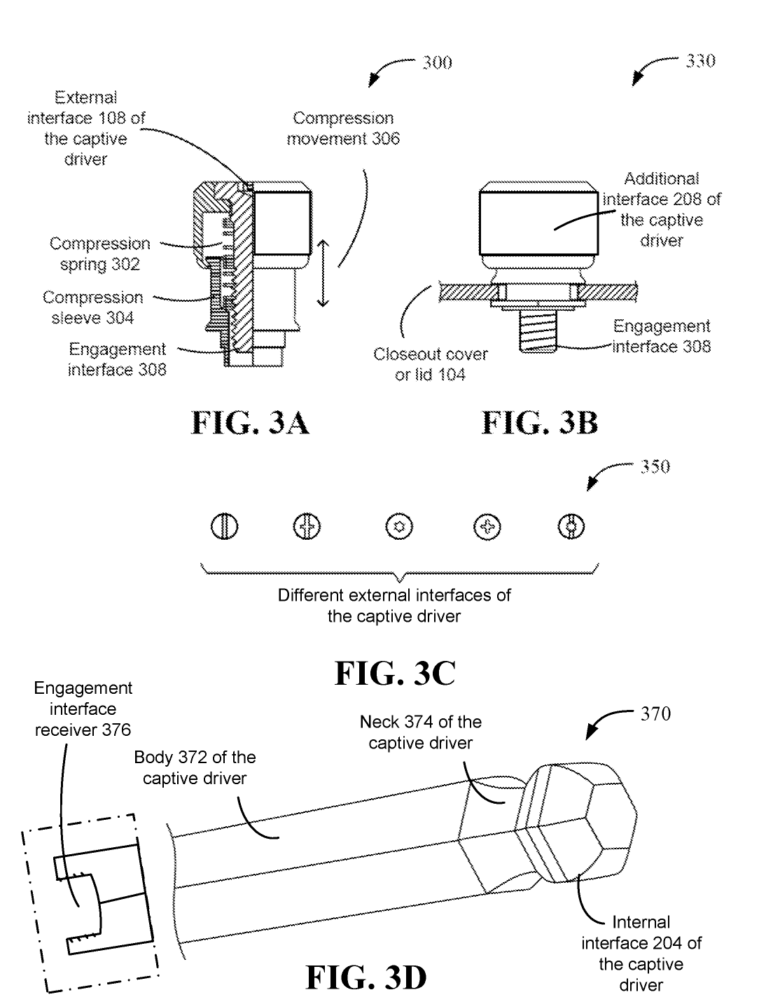

In another example, the additional interface 208 may be used together with the external interface 108 to provide a singular torquing 214 for the captive driver 202. In yet another example, the additional interface 208 may be used to provide a compression movement 306 (such as in FIG. 3A) for the external interface 108, prior to the external interface 108 used to provide an internal torquing 216 for the captive driver 202. The internal torquing 216 of the captive driver may be passed or may cause a wedge torquing 218 for the wedgelock 210. FIG. 2A also illustrates that the wedge torquing 218 may cause parts of the wedgelock 210 or at least a locking feature 252 (also in FIG. 2B) to expand circumferentially or outwards, and into a receiving feature 254 (also in FIG. 2B). The expansion, circumferentially or outwards, may lock the wedgelock 210 between the circuit board or card 106 and a side surface 220 of the electronics box 102. The locking of the wedgelock 210 also locks the circuit board or card 106 to the electronics box 102. A torquing 214, 216, 218 in an opposite direction may unlock the wedgelock 210 and may unlock the circuit board or card 106.

FIG. 2A also illustrates a callout 226 with an alternate example of a captive driver 202. The alternate example may include a captive driver 202 which is integrated, as a single piece, with a sleeve. The sleeve may extend outside a closeout cover or lid 104. The sleeve may be a compression sleeve, as in FIG. 3A. The sleeve may provide an external section (such as the section illustrated as above the closeout cover or lid 104). The external section may not be wider than the access feature 206. This allows the captive driver 202 to be installed through the access feature 206 and to receive one or more of an external interface or an additional interface, as detailed further in connection with FIG. 3A, for instance. One or more of the external interface or the additional interface used with the integrated version of the captive driver 202 to maintain the captive driver 202 in position from above the closeout cover or lid 104. A washer or an integrated feature of the captive driver 202 and which may be wider than the access feature 206 may be used under the closeout cover or lid 104 to maintain the captive driver 202 in the position from below the closeout cover or lid 104. The integrated version of the captive driver 202 illustrates an example in which unique part requirements are reduced. The reduction in the unique part requirements simplifies installation, removal, access, or maintenance of a system which includes the captive driver.

FIG. 2B illustrates further aspects 250 of a captive driver in a cross-section of the electronics box, in accordance with a further non-limiting aspect of the present disclosure. The internal interface 204 of the captive driver 202 may be removably or fixedly associated with a wedgelock interface 212 of the wedgelock 210. The captive driver 202 may include an external interface 108 which may be removably or fixedly associated with the captive driver 202. FIG. 2B also illustrates the access feature 206 of the closeout cover or lid 104 for the external interface to be extended or allowed for access 114 outside the electronics box 102. FIG. 2B also illustrates that the wedge torquing 218 may cause parts of the wedgelock 210 or at least a locking feature 252 to expand circumferentially or outwards, and into a receiving feature 254. The expansion, circumferentially or outwards, may lock the wedgelock 210 between the circuit board or card 106 and a side surface 220 of the electronics box 102. The locking of the wedgelock 210 also locks the circuit board or card 106 to the electronics box 102. A torquing, as detailed in FIG. 2A, performed in an opposite direction, may unlock the wedgelock 210 and may unlock the circuit board or card 106. FIG. 2B illustrates that the wedgelock may be an elongated structural member having a length similar, slightly more, or slightly less than the depth (or length) of a circuit board or card 106.

FIG. 3A illustrates aspects 300 of an external interface and an additional interface of the captive driver prior to a compression movement to engage the captive driver, in accordance with a further non-limiting aspect of the present disclosure. The aspects 300 illustrated include that the external interface 108 of the captive driver 202 may be associated with a compression spring 302 to allow engagement of the external interface 108 with the captive driver 202 upon compression (such as by a compression movement 306) of the compression spring 302. There may be a compression sleeve 304 provided to retain the compression spring 302 and to allow the compression movement 306 for the external interface 108 with respect to the captive driver 202.

FIG. 3A also illustrates that the external interface 108 is removably associated with the captive driver 202 by an engagement interface 308. In one example, the engagement interface 308 may be a threaded screw capable of threading into an end, which is opposite the internal interface 204, of the captive driver 202. The removable association allows an initial part of the torquing 214 operation that may not be passed to the captive driver 202 to allow the engagement of one or more of the external interface 108 or the additional interface 208 of the captive driver 202. Once engagement occurs, then all the torquing 214 may be passed to the captive driver 202. In another example, all of the torquing 214 may be passed to the captive driver without need for engagement if the captive driver is already engaged with one or more of the external interface 108 or the additional interface 208. This may be performed by associating the compression sleeve 304 to the captive driver, whereas the external interface 108 and the additional interface 208 may be subject to the compression movement 306 to engage and immediately torque the captive driver 202.

FIG. 3B illustrates aspects 330 of the external interface and the additional interface of the captive driver after a compression movement to engage the captive driver, in accordance with a further non-limiting aspect of the present disclosure. As illustrated, relative to FIG. 3A, the external interface 108 and the additional interface 208 of the captive driver 202 are compressed (to allow the engagement interface 308 to extend out of at least the additional interface 208). FIG. 3B does not illustrate the captive driver to make it apparent that the compression movement 306 allows extension of the engagement interface 308 to engage the captive driver 202 to immediately or subsequently cause an internal torque 216 to the captive driver 202, through the access feature 206 of the closeout cover or lid 104.

FIG. 3C illustrates different interchangeable external interfaces 350 usable with a captive driver in a system for locking or unlocking a circuit board or card in an electronics box, in accordance with a further non-limiting aspect of the present disclosure. In at least one example, at least some of the external interfaces 350 may be standard interfaces while other examples of the external interfaces 350 may include security interfaces capable of movement only with an insert-based tool 216, for instance. For example, it is possible to determine an application or a requirement of the electronics box 102 or the circuit board or card 106. For instance, if there are existing tools associated with the electronics box 102 or the circuit board or card 106, then selection of one of the external interfaces 350 to use the existing tools (such as the same insert-based tool 224) may performed.

FIG. 3D illustrate aspects 370 of a captive driver, in accordance with a further non-limiting aspect of the present disclosure. FIG. 3D illustrates that a captive driver 202 may include a body 372, one or more necks 374 (such as on either ends or on only one end), an internal interface 204 on at least one end, and an engagement interface receiver 376 on an opposite end (relative to the internal interface 204). The engagement interface receiver 376 is able to removably or fixedly receive the engagement interface 308 of the external interface 108. In one example, the body 372 of the captive driver 202 may have a length suitable to or determined for the application, including for dimensions of the electronics box 102 or for dimensions between the closeout cover or lid 104 and slots (such as in FIG. 4A) for the circuit board or card 016.

FIG. 4A illustrates aspects 400 of an electronics box 102, in accordance with a further non-limiting aspect of the present disclosure. The aspects 400 illustrated that each circuit board or card 106 may be associated with two captive drivers and wedgelocks 402, 404, one on each side of the circuit board or card 106. There may be two distinct external interfaces provided to access and cause a lock and unlock for the respective ones of the two captive drivers and wedgelocks 402, 404. FIG. 4A also illustrates that each circuit board or card 106 may be associated with a closeout cover or lid 104. In another example, there may be a single closeout cover or lid 104 over multiple circuit boards or cards, across additional slots 406 of an electronics box 102. FIG. 4A illustrates that the circuit boards or cards may be provided with the closeout cover or lids, the captive drivers, and the wedgelocks, altogether, for installation into the electronics box 102 or for replacement with respect to the electronics box 102.

FIG. 4B illustrates aspects 430 of a captive driver and its engagement with the external interface and the additional interface using a seal, in accordance with a further non-limiting aspect of the present disclosure. The aspects 430 illustrate, like in FIG. 3D, that a captive driver 202 may include a body 372, one or more necks 374 (such as on either ends or on only one end), and an internal interface 204 on at least one end. The aspects 430 also illustrate that the captive driver 202 may include a compression spring 436 within a compression sleeve 434. These compression features may be distinct from the compression spring 302 within a compression sleeve 304 associated with the external interface 108, in FIG. 3A.

In one example, the compression sleeve 434 of the internal interface 204 may be used to handle excess impacts or pressure applied to the captive driver and to prevent such excess impacts or pressure from reaching the wedgelock 210 or damaging other internal hardware of the electronics box 102. The compression sleeve 434 may contact a top of the wedgelock and absorbs the excess impacts or pressure prior to reaching the wedgelock 210, while the internal interface 204 may engage the wedgelock interface 212. In another example, the compression spring 436 within a compression sleeve 434 of the internal interface 204 may be used for engagement, between the captive driver 202 and the wedgelock 210, different than the external interface 108, described in FIG. 3A. For example, the compression spring 436 being compressed may allow a releasable association of the internal interface 204 with a wedgelock interface 212.

FIG. 4C illustrates aspects 450 of a captive driver and an engagement interface of the external interface and the additional interface to the captive driver, in accordance with a further non-limiting aspect of the present disclosure. FIG. 4C illustrates that the captive driver 202 may be selected or determined for use in an application based on different wedgelock interfaces 452 available in circuit boards or cards 106 of an electronic box 102. The captive driver 202 may be selected based in part on an existing wedgelock 210 used and, specifically, based in part on a wedgelock interface of the existing wedgelock 210 used. For example, if a hexagonal wedgelock interface is provided with a wedgelock of a circuit board or card, then a captive driver having a hexagonal wedgelock interface of the available wedgelock interfaces 452 may be selected or determined to be used with the wedgelock.

FIG. 4C also supports the use of interchangeable internal interfaces 204 for a captive driver 202. For example, there may be interchangeable internal interfaces to match the wedgelock interfaces 452 illustrated. In another example, the interchangeable internal interfaces may include the body 372 of the captive driver 202 so that only the external interface 108 is to be added to a selected or determined one of the interchangeable internal interfaces to be used with a wedgelock. As such, a selected or determined one of the interchangeable internal interfaces may be used based at least in part on an application or a requirement of the wedgelock. FIGS. 4B and 4C also illustrate that a neck 374 of the captive driver 202 may have a seal 432 at the side of the external interface 108 and the access feature 206 of the closeout cover or lid 104. The seal is able to protect the captive driver 202 from the environment 112 outside the electronics box 102.

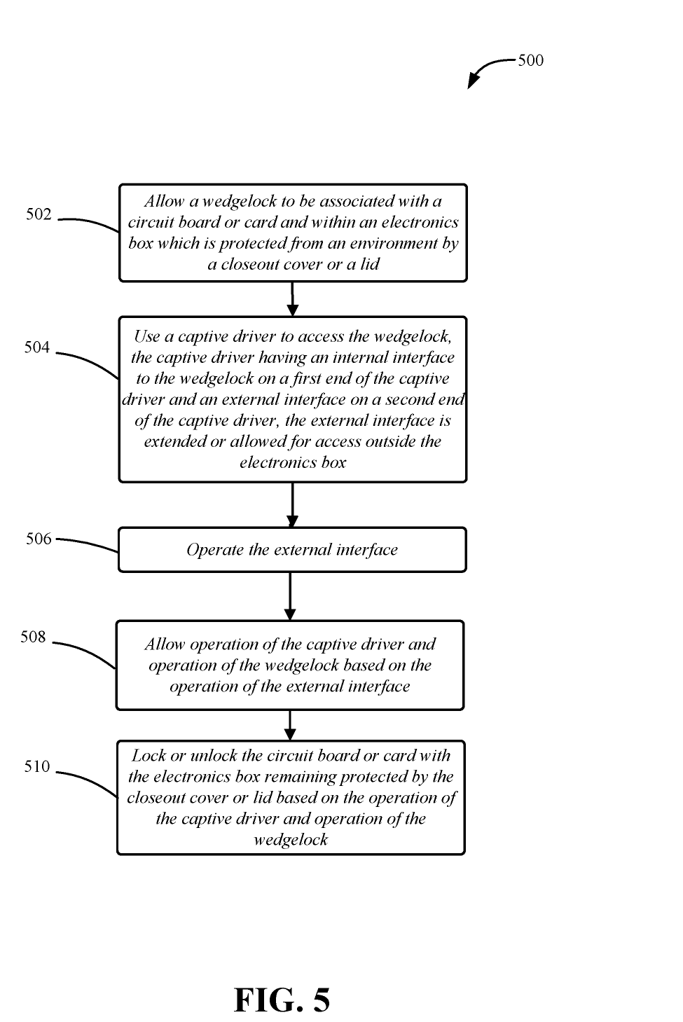

FIG. 5 illustrates a method or process 500 associated with a system for locking or unlocking a circuit board or card in an electronics box, in accordance with a further non-limiting aspect of the present disclosure. The method 500 may include a step to allow 502 a wedgelock to be associated with a circuit board or card and to be within an electronics box which is protected from an environment by a closeout cover or a lid. The method 500 may include a step to use 504 a captive driver to access the wedgelock. The captive driver may have an internal interface to the wedgelock on a first end of the captive driver and may have an external interface on a second end of the captive driver. The external interface may be extended or allowed for access outside the electronics box. The method 500 may include a step to operate 506 the external interface. The method 500 may include a step to allow 508 operation of the captive driver and operation of the wedgelock based on the operation of the external interface. The method 500 may include a step to lock or unlock 510 the circuit board or card with the electronics box remaining protected by the closeout cover or lid, based on the operation of the captive driver and operation of the wedgelock.

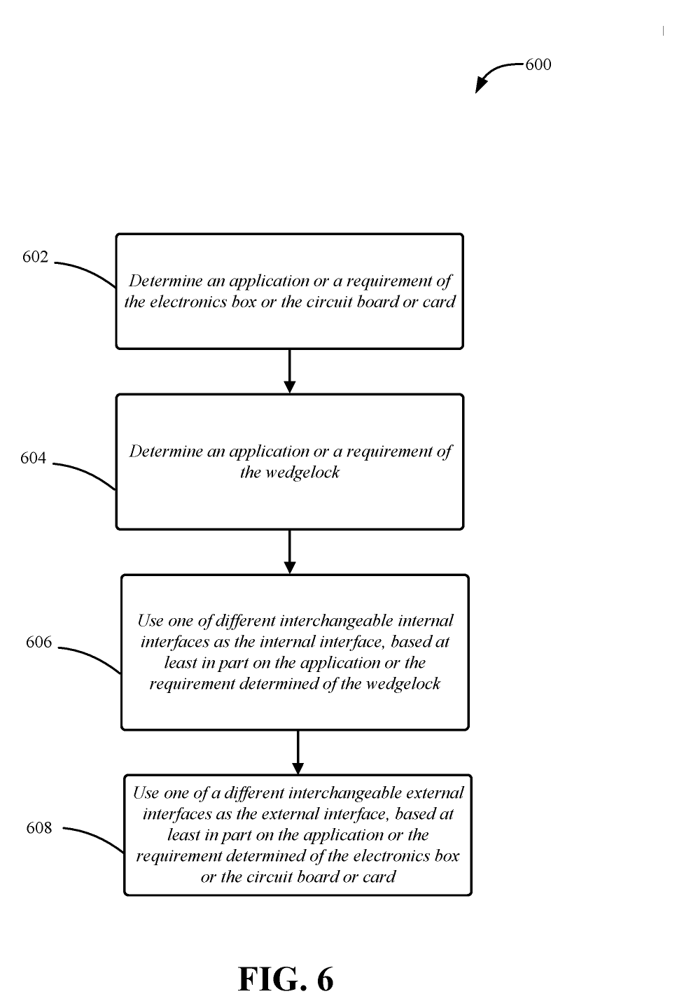

FIG. 6 illustrates a further method or process 600 associated with a system for locking or unlocking a circuit board or card in an electronics box, in accordance with a further non-limiting aspect of the present disclosure. The method 600 in FIG. 6 may be used with or separately from the method 500 in FIG. 5. For example, the method 600 in FIG. 6 may be used for locking or unlocking a circuit board or card in an electronics box based on different wedgelocks or different applications or requirements of the electronic box or the circuit board or card. The method 600 may include a step to determine 602 an application or a requirement of the electronics box or the circuit board or card. The method 600 may include a step to determine 604 an application or a requirement of the wedgelock. The method 600 may include a step to use 606 one of different interchangeable internal interfaces as the internal interface, in the method 500 of FIG. 5, based at least in part on the application or the requirement determined of the wedgelock. The method 600 may include a step to use 608 one of a different interchangeable external interfaces as the external interface, in the method 500 of FIG. 5, based at least in part on the application or the requirement determined of the electronics box or the circuit board or card.

The methods 500, 600 may include a further step or a sub-step to engage the external interface with the captive driver upon compression of a compression spring associated with the captive driver. A compression sleeve may be used to retain the compression spring with the captive driver and to allow compression movement for the external interface with respect to the captive driver. The methods 500, 600 may include a further step or a sub-step to allow, using an additional interface over the external interface, a grasp-based torquing of the captive driver through the additional interface. The methods 500, 600 may include a further step or a sub-step to allow, using the external interface, only an insert-based torquing of the captive driver.

The present disclosure has been described with reference to various exemplary and illustrative aspects. The aspects described herein are understood as providing illustrative features of varying detail of various aspects of the disclosed disclosure; and therefore, unless otherwise specified, it is to be understood that, to the extent possible, one or more features, elements, components, constituents, ingredients, structures, modules, and/or aspects of the disclosed aspects may be combined, separated, interchanged, and/or rearranged with or relative to one or more other features, elements, components, constituents, ingredients, structures, modules, and/or aspects of the disclosed aspects without departing from the scope of the disclosed disclosure. Accordingly, it will be recognized by persons having ordinary skill in the art that various substitutions, modifications or combinations of any of the exemplary aspects may be made without departing from the scope of the disclosure. In addition, persons skilled in the art will recognize or be able to ascertain using no more than routine experimentation, many equivalents to the various aspects of the disclosure described herein upon review of this specification. Thus, the disclosure is not limited by the description of the various aspects, but rather by the claims.

What is claimed is:

1. A system for locking or unlocking a circuit board or card in an electronics box, the system comprising:
a wedgelock associated with the circuit board or card and within the electronics box, wherein the electronics box is protected from an environment by a closeout cover or a lid; and
a captive driver comprising a first interface to the wedgelock on a first end of the captive driver and comprising a second interface on a second end of the captive driver, wherein the second interface is extended or allowed for access outside the electronics box, and wherein operation of the second interface allows operation of the captive driver and operation of the wedgelock to lock or unlock the circuit board or card with the electronics box remaining protected by the closeout cover or lid.

2. The system of claim 1, wherein the first interface of the captive driver is removably or fixedly associated with a wedgelock interface of the wedgelock and wherein the second interface of the captive driver is removably or fixedly associated with the captive driver.

3. The system of claim 1, further comprising:
an access feature of the closeout cover or lid for the second interface to be extended or allowed for access outside the electronics box.

4. The system of claim 3, further comprising:
a seal between the access feature and the second interface, the seal to support protection to the electronics box from the environment.

5. The system of claim 1, further comprising:
a compression spring to allow engagement of the second interface with the captive driver upon compression of the compression spring.

6. The system of claim 5, further comprising:
a compression sleeve to retain the compression spring and to allow compression movement for the second interface with respect to the captive driver.

7. The system of claim 1, further comprising:
a plurality of interchangeable second interfaces, wherein one of the plurality of interchangeable second interfaces is to be used as the second interface, based at least in part on an application or a requirement of the electronics box or the circuit board or card.

8. The system of claim 1, further comprising:
an additional interface over the second interface to allow grasp-based torquing of the captive driver through the additional interface, wherein the second interface only allows an insert-based torquing of the captive driver.

9. The system of claim 1, further comprising:
a plurality of interchangeable first interfaces, wherein one of the plurality of interchangeable first interfaces is to be used as the first interface, based at least in part on an application or a requirement of the wedgelock.

10. A captive driver comprising a first interface on a first end of the captive driver and comprising a second interface on a second end of the captive driver, wherein the captive driver is to be associated with a circuit board or card within an electronics box which is protected from an environment by a closeout cover or a lid, wherein the second interface is to extend or is allowed to access the environment outside the electronics box, and wherein operation of the second interface allows operation of the captive driver and operation of a wedgelock to lock or unlock the circuit board or card with the electronics box remaining protected by the closeout cover or lid.

11. The captive driver of claim 10, wherein the first interface of the captive driver is removably or fixedly associated with a wedgelock interface of the wedgelock and wherein the second interface of the captive driver is removably or fixedly associated with the captive driver.

12. The captive driver of claim 10, wherein the second interface is associated with a compression spring to allow engagement of the second interface with the captive driver upon compression of the compression spring.

13. The captive driver of claim 12, wherein the second interface is associated with a compression sleeve to retain the compression spring and to allow compression movement for the second interface with respect to the captive driver.

14. The captive driver of claim 10, wherein the captive driver is able to receive one of a plurality of interchangeable second interfaces to be used as the second interface, based at least in part on an application or a requirement of the electronics box or the circuit board or card.

15. The captive driver of claim 10, wherein the captive driver is able to receive one of a plurality of interchangeable first interfaces to be used as the first interface, based at least in part on an application or a requirement of the wedgelock.

16. A method for locking or unlocking a circuit board or card in an electronics box, the method comprising:
allowing a wedgelock to be associated with the circuit board or card and within the electronics box, wherein the electronics box is protected from an environment by a closeout cover or a lid;
using, to access the wedgelock, a captive driver comprising a first interface to the wedgelock on a first end of the captive driver and comprising a second interface on a second end of the captive driver, wherein the second interface is extended or allowed for access outside the electronics box; and
operating the second interface to allow operation of the captive driver and operation of the wedgelock to lock or unlock the circuit board or card with the electronics box remaining protected by the closeout cover or lid.

17. The method of claim 16, further comprising:
engaging the second interface with the captive driver upon compression of a compression spring associated with the captive driver, wherein a compression sleeve retains the compression spring with the captive driver and allows compression movement for the second interface with respect to the captive driver.

18. The method of claim 16, further comprising:
determining an application or a requirement of the electronics box or the circuit board or card; and
using one of a plurality of interchangeable second interfaces as the second interface, based at least in part on the application or the requirement determined of the electronics box or the circuit board or card.

19. The method of claim 16, further comprising:
determining an application or a requirement of the wedgelock; and
using one of a plurality of interchangeable first interfaces as the first interface, based at least in part on the application or the requirement determined of the wedgelock.

20. The method of claim 16, further comprising:
allowing, using an additional interface over the second interface, a grasp-based torquing of the captive driver through the additional interface; and
allowing, using the second interface, only an insert-based torquing of the captive driver.
